(19) United States
(12) Patent Application Publication
(10) Pub. No.: US 2024/0006180 A1
(43) Pub. Date: Jan. 4, 2024

(54) LOW RESISTANCE PULSED CVD TUNGSTEN

(71) Applicant: Lam Research Corporation, Fremont, CA (US)

(72) Inventors: Yu PAN, San Jose, CA (US); Yao-Tsung HSIEH, San Jose, CA (US); Xiaolan BA, Fremont, CA (US); Juwen GAO, San Jose, CA (US)

(21) Appl. No.: 18/253,196

(22) PCT Filed: Nov. 16, 2021
(86) PCT No.: PCT/US2021/059473

§ 371 Date: May 18, 2023

Related U.S. Application Data
(60) Provisional application No. 63/198,891, filed on Nov. 20, 2020.

(51) Int. Cl. H01L 21/285; H01L 21/28; H01L 21/768; C23C 16/14; C23C 16/02; C23C 16/04; C23C 16/455

(52) U.S. Cl. CPC H01L 21/28562; H01L 21/28079; H01L 21/76879; C23C 16/14; C23C 16/0272; C23C 16/045; C23C 16/45525

(57) ABSTRACT

Provided herein are methods of depositing tungsten (W) films without depositing a nucleation layer. In certain embodiments, the methods involve depositing a conformal layer of boron (B) on a substrate. The substrate generally includes a feature to be filled with tungsten with the boron layer conformal to the topography of the substrate including the feature. The reducing agent layer is then exposed to a continuous flow of hydrogen and pulses of fluorine-containing tungsten precursor in a pulsed CVD process. The conformal boron layer is converted to a conformal tungsten layer.

### INCORPORATION BY REFERENCE

A PCT Request Form is filed concurrently with this specification as part of the present application. Each application that the present application claims benefit of or priority to as identified in the concurrently filed PCI Request Form is incorporated by reference herein in its entirety and for all purposes.

### BACKGROUND

Deposition of conductive materials such as tungsten films is an integral part of many semiconductor fabrication processes. These materials may be used for horizontal interconnects, vias between adjacent metal layers, contacts between metal layers and devices on the silicon substrate, and high aspect ratio features. As devices shrink and more complex patterning schemes are utilized in the industry, deposition of thin tungsten films becomes a challenge. These challenges include depositing low resistivity films having good step coverage.

The background and contextual descriptions contained herein are provided solely for the purpose of generally presenting the context of the disclosure. Much of this disclosure presents work of the inventors, and simply because such work is described in the background section or presented as context elsewhere herein does not mean that it is admitted to be prior art.

### SUMMARY

Provided herein are methods of depositing tungsten (W) films without depositing a nucleation layer. In certain embodiments, the methods involve depositing a conformal layer of boron (B) on a substrate. The substrate generally includes a feature to be filled with tungsten with the boron layer conformal to the topography of the substrate including the feature. The reducing agent layer is then exposed to a continuous flow of hydrogen and pulses of fluorine-containing tungsten precursor in a pulsed CVD process. The conformal boron layer is converted to a conformal tungsten layer.

One aspect of the disclosure relates to a method including depositing a tungsten bulk layer without depositing a tungsten nucleation layer on a surface of a substrate by forming a layer including elemental boron (B) on the surface; and after forming the layer, performing a pulsed chemical vapor deposition process.

One aspect relates to a method including: depositing a tungsten bulk layer without depositing a tungsten nucleation layer on a surface of a substrate by: forming a layer including elemental boron (B) on the surface; and after forming the layer, performing a pulsed chemical vapor deposition (CVD) process to convert the layer including elemental boron to a tungsten layer, wherein the pulsed CND process includes exposing the substrate to a continuous flow of hydrogen (H₂) and while exposing the substrate to a continuous flow of H₂, exposing the substrate to pulses of a tungsten precursor separated by intervals.

In some embodiments, the B content at the interface of the elemental tungsten bulk layer and the surface is no more than 10²¹ atoms/cm³.

In some embodiments, the layer including elemental boron is between 10 and 50 Angstroms thick. In some embodiments, the layer including elemental boron consists essentially of boron. In some embodiments, the surface is a nitride surface. in some embodiments, the surface is a titanium nitride surface. In some embodiments, the surface is an oxide surface. In some embodiments, forming the layer including elemental boron includes exposing the surface to diborane. In some embodiments, the operations of forming the layer including elemental boron and performing the pulsed CVD process are performed in the same chamber. In some embodiments, forming a layer including elemental boron (B) on the surface includes thermal decomposition of a boron-containing reducing agent without adsorption of the boron-containing reducing agent on the surface.

In some embodiments, the substrate includes one or more features to be filled with tungsten. In some embodiments, the layer of elemental boron conforms to the surface topography. In some embodiments, the method further includes, after converting the layer including elemental boron to a tungsten layer, continuing the pulsed CVD process to deposit tungsten in the feature. In some embodiments, the method further includes, after converting the layer including elemental boron to a tungsten layer, performing an ALD process to deposit tungsten in the feature.

In some embodiments, the ALD process is performed in a different chamber as the pulsed CVD process. In some embodiments, the ALD process is performed in the same chamber as the pulsed CVD process. In some embodiments, the method includes exposing the tungsten layer to an inhibition chemistry prior to the ALD process. In some embodiments, the inhibition chemistry is nitrogen-containing.

In some embodiments, the duration of the pulses of tungsten precursor is less than the duration of the intervals between pulses.

In some embodiments, the pulsed. CVD process is performed at a temperature of no more than 350° C. In some embodiments, the pulsed CVD process is performed at a temperature of no more than 300° C. In some embodiments, the layer of tungsten is between 10 and 50 Angstroms thick.

Apparatuses to perform the methods are also provided.

These and other aspects of the disclosure are discussed further below with reference to the drawings.

### BRIEF DESCRIPTION OF DRAWINGS

FIGS. 1A and 1B depict example metal stacks that include bulk tungsten.

FIG. 2 depicts a schematic example of a buried wordline (bWL) structure that includes tungsten.

FIG. 3A depicts a schematic example of tungsten wordlines in a 3D NAND structure.

FIG. 3B depicts a detail of the interface between a tungsten wordline and an oxide layer in a 3D NAND structure.

FIG. 3C depicts a schematic cross-sectional side view of a partially fabricated 3-D NAND structure.

FIG. 3D depicts a schematic top view of a partially fabricated 3-D NAND structure.

FIG. 4 is a process flow diagram illustrating operations of a method of depositing a bulk tungsten layer without a nucleation layer.

FIGS. 5A and SB show examples of pulsed flow sequences may be used to deposit boron (B) layers.

FIG. 6 shows an example of a flow sequence for a pulsed chemical vapor deposition (CVD) process that may be used to convert a B layer.

FIG. 7A is a process flow diagram illustrating operations of a method of depositing a bulk tungsten layer without a nucleation layer.

FIG. 7B shows examples of a feature during certain operations of a method as shown in FIG. 7A.

FIGS. 8A-8J are schematic diagrams of an example of a mechanism for depositing films in accordance with disclosed embodiments.

FIG. 9 is a schematic diagram of an example process tool for performing disclosed embodiments.

FIG. 10 is a schematic diagram of an example station for performing disclosed embodiments.

FIG. 11 is a graph showing resitivity results for various tungsten deposition processes

### DETAILED DESCRIPTION

Provided herein are methods and apparatuses for forming metal films such as tungsten (W) films on semiconductor substrates. The methods involve forming a layer comprising elemental boron (B) followed by a pulsed CVD process that converts the layer of elemental boron to tungsten. In this manner, tungsten can be deposited directly on surfaces such as diffusion barrier or dielectric surfaces without deposition of a nucleation layer. During the pulsed CVD process, hydrogen (H₂) is continuously flowed while a tungsten precursor is pulsed into a chamber housing a substrate on which the tungsten is to be deposited. By using a pulsed CVD method, low resistivity films are obtained. Apparatuses to perform the methods are also provided.

Forming electrical contacts or lines in semiconductor device fabrication can involve filling features with tungsten or other electrically conductive materials. A nucleation layer can first be deposited into a via or contact. A nucleation layer is a thin conformal layer that serves to facilitate the subsequent formation of a bulk material thereon. A tungsten nucleation layer may be deposited to conformally coat the sidewalk and, if present, bottom of the feature. After the tungsten nucleation layer is deposited, bulk tungsten may be deposited on the tungsten nucleation layer. Unlike a nucleation layer, which is a thin conformal film that serves to facilitate the subsequent formation of a bulk material thereon, bulk tungsten is used to carry current. Bulk tungsten is compositionally distinct from a tungsten nucleation layer such that there is an interface between the bulk tungsten and nucleation layer. In some cases, nucleation layers have relatively high amorphous and/or beta phase content, while bulk layers have high alpha phase content. Bulk tungsten also has large grain size and lower resistivity than a nucleation layer.

There are various challenges in tungsten fill as devices scale to smaller technology nodes and more complex patterning structures are used. One challenge is distribution of material with a structure. Distribution of a material within a feature may be characterized by its step coverage. For the purposes of this description, “step coverage” is defined as a ratio of two thicknesses—the thickness of the material inside the feature divided by the thickness of the material near the opening. For purposes of this document, the term “inside the feature” represents a middle portion of the feature located about the middle point of the feature along the feature's axis, e.g., an area between about 25% and 75% of the distance or, in certain embodiments, between about 40% and 60% of the distance along the feature's depth measured from the feature's opening, or an end portion of the feature located between about 75% and 95% of the distance along the feature's axis as measured from the opening. The term “near the opening of the feature” or “near the feature's opening” represents a top portion of the feature located within 25% or, more specifically, within 10% of the opening's edge or other element representative of the opening's edge. Step coverage of over 100% can be achieved, for example, by filling a feature wider in the middle or near the bottom of the feature than at the feature opening.

Another challenge is reducing resistance in the deposited tungsten films. Thinner films tend to have higher resistance than thicker films. As features become smaller, the tungsten contact or line resistance increases due to scattering effects in the thinner tungsten films. Low resistivity tungsten films minimize power losses and overheating in integrated circuit designs. Tungsten nucleation layers typically have higher electrical resistivities than the overlying bulk layers. Further, tungsten nucleation films occupy a larger percentage of smaller features, increasing the overall resistance in the feature. Resistivity of a tungsten film depends on the thickness of the film deposited, such that resistivity increases as thickness decreases due to boundary effects.

As described above, one aspect of the disclosure relates to methods of depositing tungsten films without depositing a nucleation layer. In certain embodiments, the methods involve depositing a conformal layer of boron (B) on a substrate. The substrate generally includes a feature to be filled with tungsten, with the boron layer conformal to the topography of the substrate including the feature. The boron layer is then exposed to continuous flow of hydrogen and pulses of a tungsten precursor. The conformal boron layer is converted to a conformal tungsten layer.

According to various embodiments, one or more of the following advantages may be realized using the methods described herein. Tungsten films deposited using the nucleation-free methods described herein can have lower resistivity than tungsten films deposited on nucleation layers. Tungsten films deposited using the pulsed CVD nucleation-free methods described herein can have lower boron concentration than tungsten films deposited on nucleation layers formed using boron-containing reducing agents. Tungsten films deposited using the pulsed CVD nucleation-free methods described herein can have large grain size without a grain boundary at nucleation-bulk interface. Tungsten films deposited using the pulsed CVD nucleation-free methods have lower resistivity than films formed without pulsing. Tungsten films deposited using the pulsed CVD nucleation-free methods have better step coverage than films formed without pulsing. Tungsten films deposited using the pulsed CVD nucleation-free methods have less fluorine impurities than films formed without pulsing.

In some embodiments, the conversion described above occurs as part of a bulk tungsten deposition process. The bulk tungsten deposition process may use H₂ as a reducing agent and grow tungsten bulk film from the substrate surface on which the B layer was previously deposited. Unlike a bulk film deposited on a nucleation layer, the resulting tungsten film stack has no nucleation layer/bulk layer interface. In some embodiments, the pulsed CVD process can be continued to grow the tungsten bulk film.

In some embodiments, the tungsten layer formed by converting the boron layer functions as a large grain templating layer. Subsequent bulk deposition (which may be a CVD or atomic layer deposition (ALD) deposition process, for example) continues the grain growth, forming large grain, low resistivity films.

In some embodiments, the boron layer and the subsequent tungsten layer is formed directly on a nitride surface, such as titanium nitride (TiN) or tungsten carbon nitride (WCN) layer. In some embodiments, the boron layer and the subsequent tungsten layer is formed directly on an oxide surface, such as a silicon oxide (e.g., SiO₂) or aluminum oxide (e.g., Al₂O₃) surface. This eliminates the need for an adhesion/barrier layer such as a TiN layer or titanium/titanium nitride (Ti/TiN) bilayer.

Methods described herein are performed on a substrate that may be housed in a chamber. The substrate may be a silicon wafer, e.g., a 200-mm wafer, a 300-mm wafer, or a 450-mm wafer, including wafers having one or more layers of material, such as dielectric, conducting, or semi-conducting material deposited thereon.

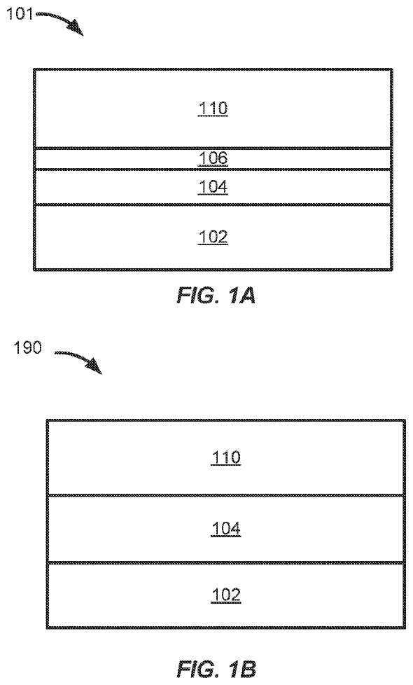

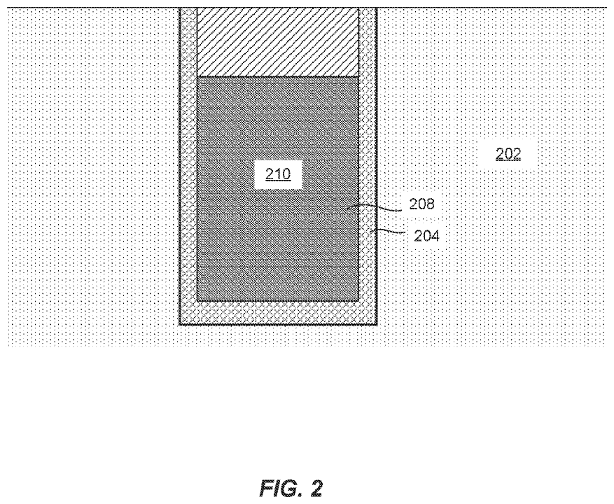

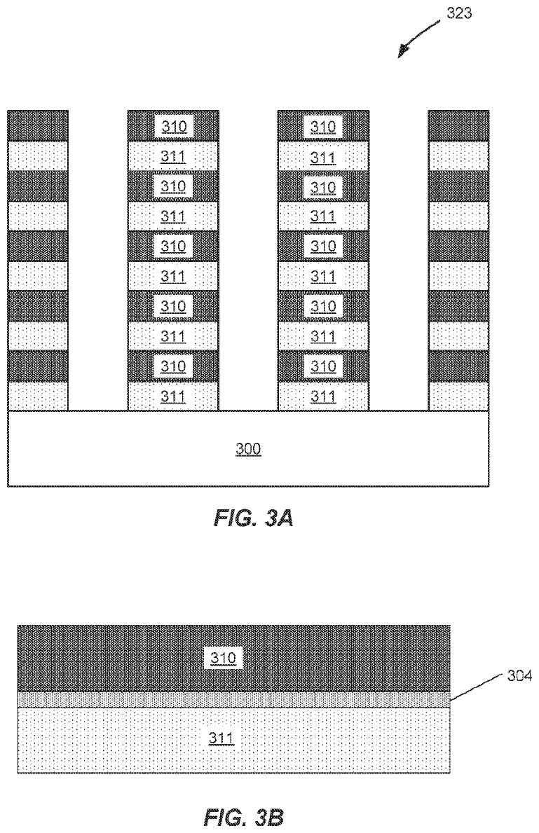

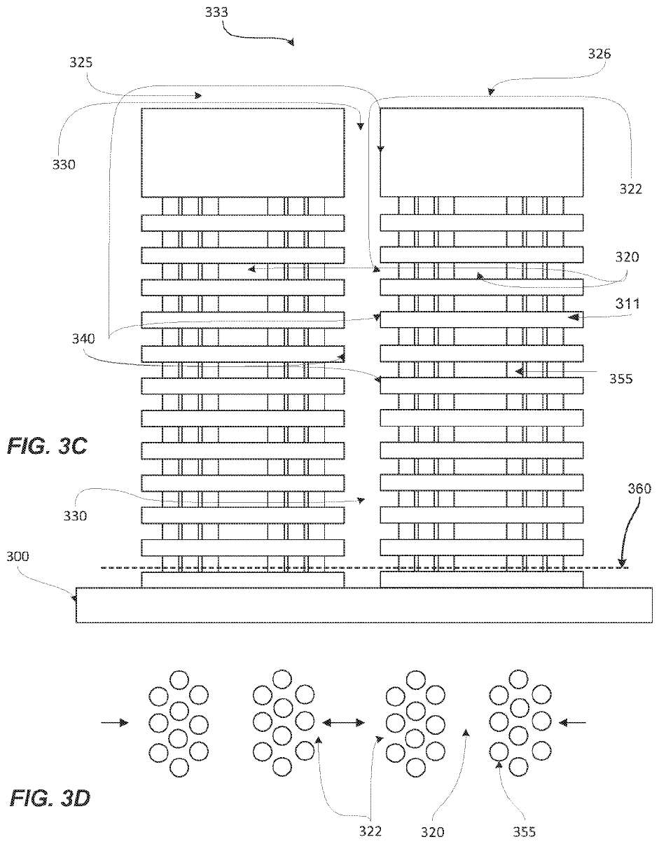

FIGS. 1A and 1B are schematic examples of material stacks that include a bulk tungsten layer directly contacting on an underlying layer without an intervening nucleation layer. FIGS. 1A and 1B illustrate the order of materials in a particular stack and may be used with any appropriate architecture and application, as described further below with respect to FIGS. 2, 3A, and 3B. In the example of FIG. 1A, a substrate 102 has a nucleation layer 108 deposited thereon. The substrate 102 may be a silicon or other semiconductor wafer, e.g., a 200-mm wafer, a 300-mm wafer, or a 450-mm wafer, including wafers having one or more layers of material, such as dielectric, conducting, or semi-conducting material deposited thereon. The methods may also be applied to form metallization stack structures on other substrates, such as glass, plastic, and the like.

In FIG. 1A, a dielectric layer 104 is on the substrate 102. The dielectric layer 104 may be deposited directly on a semiconductor (e.g., Si) surface of the substrate 102, or there may be any number of intervening layers. Examples of dielectric layers include doped and undoped silicon oxide, silicon nitride, and aluminum oxide layers, with specific examples including doped or undoped layers SiO2 and Al2O3. Also, in FIG. 1A, a diffusion barrier layer 106 is disposed between and the dielectric layer 104 and a bulk tungsten layer 110. Examples of diffusion barrier layers including titanium nitride (TiN), titanium/titanium nitride (Ti/TiN), tungsten nitride (WN), and tungsten carbon nitride (WCN). The bulk tungsten layer 110 is deposited on the diffusion barrier layer 106 and is the main conductor (also referred to as a bulk conductor or bulk layer) of the structure.

FIG. 1B shows another example of a material stack 190. In this example, the stack includes the substrate 102, dielectric layer 104, with the bulk tungsten layer 110 deposited directly on the dielectric layer 104, without an intervening diffusion barrier layer. As in the example of FIG. 1A, a bulk tungsten layer 110 is the main conductor of the structure.

While FIGS. 1A and 1B show examples of metallization stacks, the methods and resulting stacks are not so limited and include any tungsten having a tungsten bulk layer. The methods described herein are performed on a substrate that may be housed in a chamber.

The material stacks described above and further below may be implemented in a variety of structures. FIGS. 2, 3A, and 3B provide examples of structures in which the stacks may be employed. FIG. 2 depicts a schematic example of a DRAM architecture including a buried wordline (bWL) 210 in a silicon substrate 202. The bWL 210 is formed in a trench etched in the silicon substrate 202. Lining the trench is an insulating layer 204 that is disposed between the bWL 210 and the silicon substrate 202. In the example of FIG. 2, the insulating layer 204 may be a gate oxide layer, formed from a high-k dielectric material such as a silicon oxide or silicon nitride material. In some embodiments, a conformal barrier layer such as TiN or a tungsten-containing layer may be interposed between the bWL 210 and the insulating layer 204.

FIG. 3A depicts a schematic example of wordlines 310 in a 3D NAND structure 323 formed on a substrate 300. The wordlines 310 are separated by oxide layers 311. In FIG. 3B, a detail of the interface between a wordline 310 and oxide layer 311 is shown with a layer of TiN 304. In some embodiments, bulk tungsten of the tungsten wordline 310 may be deposited directly on the oxide layer 311 (or layer of aluminum oxide if present) or on a TiN or other barrier layer as described herein. Example thicknesses of wordline 310 may be between about 10 nm and 100 nm thick.

FIG. 3C presents a cross-sectional side view of a partially fabricated 3-D NAND structure 333 and illustrates challenges of metal fill. The structure 330 is formed on a semiconductor substrate 300 and includes 3D NAND stacks (left 325 and right 326), central vertical structure 330, and a plurality of stacked wordline features 320 with openings 322. on opposite sidewalls 340 of central vertical structure 330. Note that FIG. 3C displays two stacks 325 and 326 of the exhibited partially fabricated 3-D NAND structure 333, which together form the trench-like central vertical structure 330, however, in certain embodiments, there may be more than two stacks arranged in sequence and running spatially parallel to one another, the gap between each adjacent pair of stacks forming a central vertical structure 330, like that explicitly illustrated in FIG. 3C. In the example of FIG. 3C, the wordline features 320 are fluidically accessible from the central vertical structure 330 through the openings 322. Although not explicitly indicated in the figure, the horizontal features 320 present in both the 3-D NAND stacks 325 and 326 shown in FIG. 3C (i.e., the left 3-D NAND stack 325 and the tight 3-D NAND stack 326) are also accessible from the other sides of the stacks (far left and far right, respectively) through similar vertical structures formed by additional 3D-NAND stacks (to the far left and far right, but not shown). In other words, each 3-D NAND stack 325, 326 contains a stack of wordline features that are fluidically accessible from both sides of the 3-D NAND stack through a central vertical structure 330.

The wordline features in a 3-D NAND stack may be formed by depositing an alternating stack of silicon oxide and silicon nitride layers, and then selectively removing the nitride layers leaving a stack of oxide layers 311 having gaps between them. These gaps are the wordline features 320. Any number of wordlines may be vertically stacked in such a 3-D NAND structure so long as there is a technique for forming them available, as well as a technique available to successfully accomplish substantially void-free fills of the vertical features. Thus, for example, a 3D-NAND stack may include between 2 and 256 horizontal wordline features, or between 8 and 128 horizontal wordline features, or between 16 and 64 horizontal wordline features, and so forth (the listed ranges understood to include the recited end points).

FIG. 3D presents a cross-sectional top-down view of the same 3-D NAND structure shown in FIG. 3C with the cross-section taken through the horizontal section 360 as indicated by the dashed horizontal line in FIG. 3C. The cross-section of FIG. 3C illustrates several rows of pillars 355, which are run vertically from the base of semiconductor substrate 300 to the top of the 3-D NAND stacks. In some embodiments, these pillars 355 are formed from a polysilicon material and are structurally and functionally significant to the 3-D NAND structure 333. In some embodiments, such polysilicon pillars may serve as gate electrodes for stacked memory cells formed within the pillars. The top-view of FIG. 3D illustrates that the pillars 355 form constrictions in the openings 322 to wordline features 320—i.e. fluidic accessibility of wordline features 320 from the central vertical structure 330 via openings 322 (as indicated by the arrows in FIG. 3D) is inhibited by pillars 355. In some embodiments, the size of the horizontal gap between adjacent polysilicon pillars is between about 1 and 20 nm. This reduction in fluidic accessibility increases the difficulty of uniformly filling wordline features 320 with conductive material.

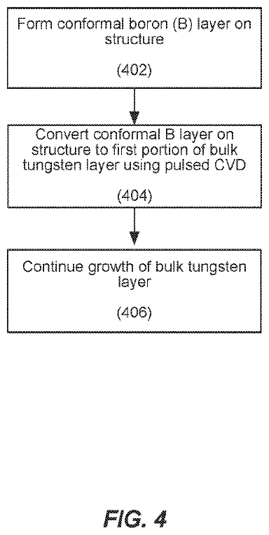

FIG. 4 is a process flow diagram of a method performed in accordance with disclosed embodiments. Operations 402-406 may be performed to deposit a bulk tungsten layer on a structure without first depositing a nucleation layer. That is, these operations are formed without prior deposition of a nucleation layer. Prior to operation 402, a substrate having a structure with one or more features to be filled without a nucleation layer may be provided to a process chamber. In some embodiments, the surface on which the bulk tungsten layer is deposited is a barrier layer such as a titanium nitride (TiN) or tungsten carbon nitride (WCN) layer. In some embodiments, the surface on which the bulk tungsten layer is deposited in an oxide or other dielectric layer.

As described below, certain operations are performed at substrate temperatures. It will be understood that substrate temperature refers to a temperature to which the pedestal holding the substrate is set.

In operation 402, a layer of boron (B) is formed on the structure. The layer is conformal in that it conforms to the shape of the structure to be filled with a tungsten bulk layer. To form the conformal layer, the structure is exposed to a boron-containing gas, which undergoes thermal decomposition. Examples of boron-containing gases include boranes such as diborane (B₂H₆), as well as BₙHₙ₊₄, BₙHₙ₊₆, BₙHₙ₊₈, BₙHₘ, where n is an integer from 1 to 10, and m is a different integer than m. The exposure may occur with a continuous flow or in pulses separated by intervals. In sonic embodiments, a carrier gas may be flowed during operation 402. In some embodiments, a carrier gas, such as nitrogen (N₂), argon (Ar), helium (He), or other inert gases, may be flowed during operation 402. If the boron-containing gas is pulsed, the carrier gas may be flowed continuously or pulsed during operation 402.

When exposing a surface to a borane, the borane may thermally decompose to form a layer of elemental boron (B) or the borane may be adsorbed onto the substrate. Elemental boron refers to boron that is chemically uncombined. In operation 402, the substrate it is exposed to a borane or other boron-containing gases using conditions under which thermal decomposition will occur. This is in contrast to nucleation layer deposition in which adsorption may be favored.

Nucleation layer deposition may involve sequential alternating pulses of a boron-containing reducing agent and tungsten-containing precursor separated by purges. The pulses are relatively short. Conditions that favor adsorption may be used at least because thermal decomposition using short pulses can lead to poor step coverage over complex structures such as 3D NAND structures. Further, during nucleation layer deposition, relatively low chamber pressures may be used to reduce fluorine incorporation when using a fluorine-containing precursor.

To favor thermal decomposition over adsorption during operation 402, temperature

may be controlled. The substrate temperature at block 402 is thus higher than the decomposition point at that pressure. For diborane, for example, a temperature of 250° C.-400° C. may be used at 40 Torr Lower temperatures (e.g., 225° C.) may be used for some compounds and conditions. It should also be known that temperatures on the higher end of the range may be harder to control. As such, for diborane, a range of 250° C.-350° C., or 250° C.-300° C. may be used. Example chamber pressures may be between 10 Torr and 90 Torr, or 10 Torr and 50 Torr. Higher pressures can improve step coverage in some embodiments. Pressure during operation 402 may be higher than generally used for nucleation layer deposition. Hydrogen (H2) may or may not be present; the addition of H2 can slow down the formation of the conformal layer. In some embodiments, operation 402 is performed without a purge during operation 402. This also enables higher pressures to be used in some embodiments with purges being more difficult at higher pressures. Thermal decomposition may also be favored by using longer pulse times and/or higher flow rates than used for nucleation layer deposition. Temperature during operation 402 may be higher than generally used for nucleation layer deposition.

According to various embodiments, the conformal layer may consist essentially of elemental boron with only a small amount of hydride (less than 5 or 1 atomic %) or other impurity present if any.

In some embodiments, the layer formed in operation 402 may include silicon, which may be formed by exposing the substrate to silicon-containing compounds such as of silane (SiH₄) and disilane (Si₂H₆). While other gases may be used, boranes and silanes may advantageously used to have a layer of B and/or Si without impurities. Thermal decomposition of silane on its own is more difficult than that of diborane; however, using silane with diborane may increase deposition rate of the conformal layer. A volumetric flow rate ratio of 1:1 B₂H₆:SiH₄ was found to provide the fastest deposition rate at 300° C. and 10 Torr; with up to 3:1 also providing good deposition rates. Having more silane than diborane results in reduced deposition rate, with the reduction increasing as the silane content increases. The B:S ratio (flow rates into the chamber as well as in the layer) may be 1:1-6:1 in some embodiments. Volumetric flow rates of B₂H₆:SiH₄ may be 0.5:1-3:1. Using both a boron-containing compound and a silicon-containing compound forms a layer including B and Si. It is possible that some amount of adsorbed silane is present in the layer. Also, in some other embodiments, silane or other silicon-containing compound only may be used to form a layer comprising elemental silicon without boron. However, as indicated above, deposition rate is much slower and decomposition is more difficult.

Still further, in some other embodiments, the conformal layer may include elemental germanium (Ge) alone or with other constituents. For any of the layers described above, the layers may consist essentially of the elemental reducing agent or mixtures of elemental reducing agents (e.g., B, B(Si), Si, etc.) or other atoms may be present. For example, SiHx, BHy, GeHz, or mixtures thereof where x, y, and z may independently be between 0 and a number that is less than the stoichiometric equivalent of the corresponding reducing agent compound may be present. A layer that consists essentially of a reducing agent will have no more than trace amounts of other atoms.

Example thicknesses of layer formed in operation 402 are 10-50 Angstroms. In some embodiments, the thickness is below 3 nm. Utile layer is too thick, it may not all be converted to tungsten; too thin, and it may not result in uniform and continuous film growth.

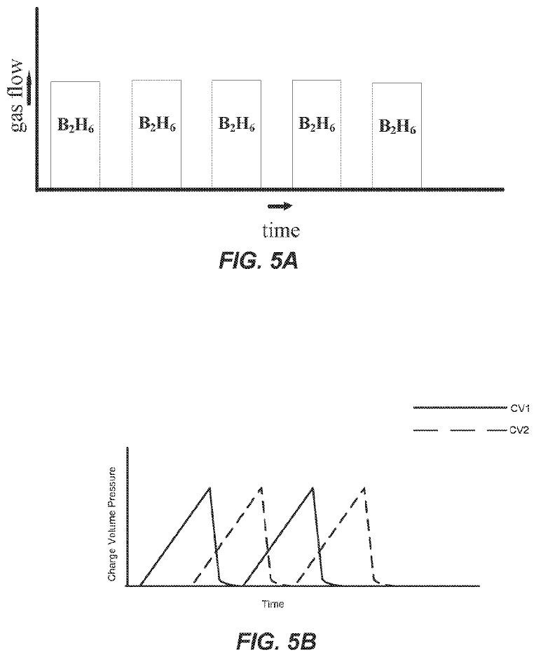

Operation 402 may be performed using continuous flow or pulses of the one or more boron-containing gas. To deposit a B layer, diborane or other boron-containing reducing agent is flowed into the deposition chamber. This may be done as a continuous flow or in pulses (see, e.g., FIG. 5A). Hydrogen or another carrier gas may or may not be present. Diborane or other boron-containing reducing gas may be provided in dilute form, e.g., 5% diborane by volume with the balance nitrogen (N2) gas. As noted above, example substrate temperatures 250° C.-350° C. or 250° C.-300° C. and chamber pressures of 10-90 Torr may be used.

FIGS. 5A and 5B depict intervals between pulses; purging in the intervals can be but is often not employed in these intervals. In some embodiments, the pulses may overlap. In some embodiments, multiple charge volumes may be used to deliver reducing agent pulses. A charge volume is a container in which a gas accumulates at a charge volume pressure. FIG. 5B shows an example of pressure of two charge volumes (CV1 and CV2) delivering sequential pulses. Each charge volume may contain the same (e.g., B₂H₆) or different (B₂H₆ and SiH₄) compounds. Use of a charge volume and especially multiple charge volumes can aid in step coverage throughout a structure. In some embodiments, the discharges may overlap.

As noted above, exposure to diborane (or another compound that is thermally decomposed to form a conformal layer) may be continuous. Example total exposure times may range from 10-30 seconds.

To deposit a B(Si) layer, higher substrate temperatures, e.g., 250° C.-400° C. may be used. Chamber pressures of 10-90 Torr may also be used for B(Si) layers. In addition to a boron-containing reducing agent, a silicon-containing reducing agent is flowed in the deposition chamber. This may take the form of sequential single B-containing reducing agent and Si-containing reducing agent pulses (or sequential multiple single B-containing reducing agent and Si-containing reducing agent pulses. In some embodiments, the B-containing and Si-containing reducing agents are co-flowed into the deposition chamber, either in a continuous flow or in pulses.

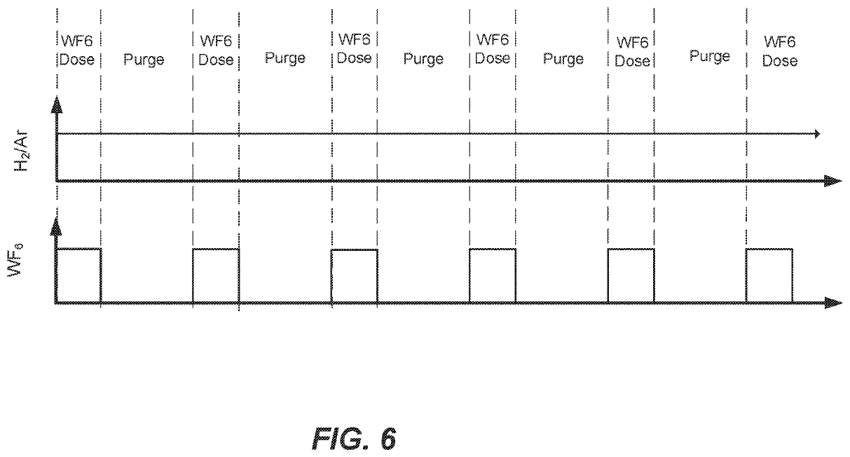

In operation 404, the conformal B layer (or other conformal layer as described above) is converted to a first portion of a bulk tungsten layer. Operation 404 involves exposing the conformal B layer to a tungsten-containing precursor, in some embodiments, a fluoride-containing tungsten precursor such as WF₆, in a pulsed CVD process. FIG. 6 shows an example timing sequence for a pulsed CVD flow. In the example of FIG. 6, argon (Ar) is co-flowed with the H₂, though another inert gas may be used with H₂ or it may be flowed alone. The flow of H₂ is continuous. WF₆ is pulsed with intervals between the pulses. The intervals are labeled purges as the continuous flow of H₂/Ar has the effect of purging WF₆ from the chamber. It should be noted that the y-axes in the example timing sequence in FIG. 6 are do not necessarily have the same scale; rather, the timing sequence is given to demonstrate the relative pulse and purge durations. The pulsed CVD process illustrated in FIG. 6 to convert the boron has a benefit of lowering resistivity of the resulting tungsten film while providing high throughput.

If the pulse is too short, the throughput may be unacceptably low. Too long, and the deposition becomes more CVD-like, with the resistivity going up. if the purge is too short, resistivity will increase. Too long, and the throughput maybe unacceptably low. According to various embodiments, these considerations may be balanced be employing a purge duration that is longer than the WF₆ pulse duration. Example purge durations being between 1 and 4 seconds and example pulse durations being between 0.5 and 2 seconds. Example purge:dose duration ratios can be 2:1 and 8:1, or 2:1 and 4:1. The grain growth on the B layer is significantly different than on an amorphous nucleation layer, with the resulting layer having large grains.

Pulsed CVD nucleation-free processes that have resistance comparable to ALD nucleation-free processes and significantly higher throughput can be achieved. Throughput of 2-4 times higher than the ALD processes can be achieved without sacrificing resistivity appreciably.

In some embodiments, pressure during operation 404 is below 20 Torr, e.g., 10 Torr, or below 10 Torr. Operation 404 generally continues until the B or B(Si) layer is fully converted. The result in a layer of elemental tungsten (W). In embodiments in which the aspect ratio of the feature is sufficiently low, higher pressures (e.g., 20 Torr, 40 Torr or greater) may be used to further improve the process throughput.

Once the B or B(Si) layer is converted, growth of the bulk tungsten layer is continued in an operation 406. In some embodiments, this can involve a continuation of the pulsed CVD process. Thus, in some embodiments, after operation 402, a pulsed CVD process as shown in FIG. 6 is performed to initiate and complete operations 404 and 406. In other embodiments, operation 406 can involve ALD deposition of bulk tungsten using H₂ a reducing agent.

Temperature during the pulsed CVD process may be the same as during the thermal decomposition, 250° C.-350° C. or 250° C.-350° C. Higher temperatures can lead to higher resistivity. Moreover, as temperatures are increased, the pulsed CVD process may form tungsten boride rather than elemental tungsten. Once the boron layer is converted to tungsten, temperature may be raised in some embodiments for operation 406. In some embodiments, the temperature during operation 406 may be between 250° C.-350° C.

If there is already a W layer formed by converting boron fully, a higher temperature for the bulk growth may not necessaraily lead to higher resistivity. In some embodiments, temperatures below 450° C. may be used, e.g., 250° C.-445° C.

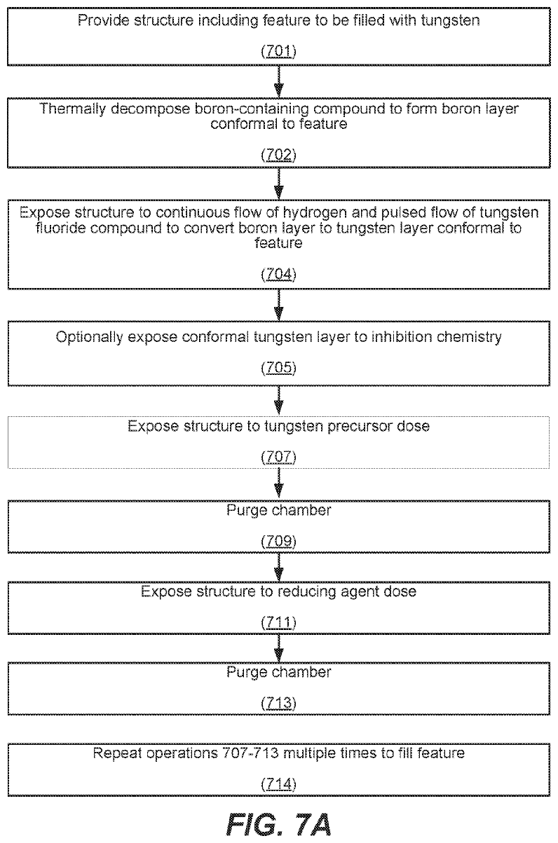

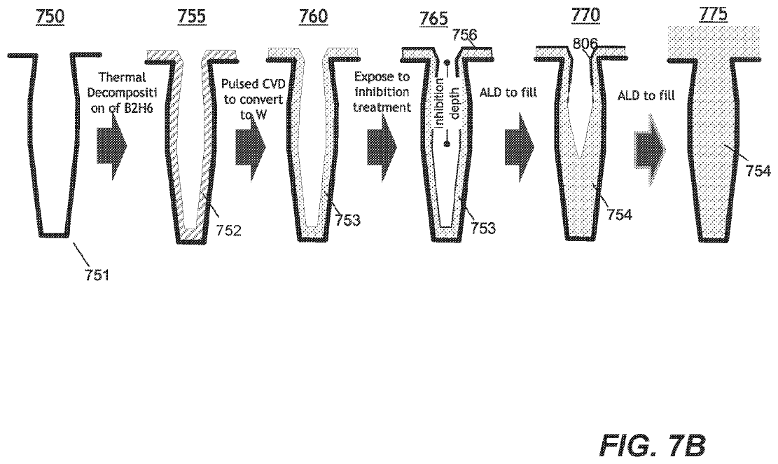

FIG. 7A provides a process flow diagram illustrating operations in depositing a tungsten bulk layer to fill a feature, with FIG. 7B showing schematic examples of a cross-section of a feature during or after certain operations of FIG. 7A. First, at operation 702, a conformal B layer is formed on a structure. This may be performed as discussed above with respect to operation 402 of FIG. 4, In some embodiments, the conformal layer is formed on a nitride barrier layer. In FIG. 7B, an unfilled feature 751 is depicted at 750. At 755, a boron layer 752 is depicted after thermal decomposition of dihorane. The boron layer 752 is conformal to the topography of the feature.

Returning to FIG. 7A, in an operation 704, the structure is exposed to a continuous flow of hydrogen and a pulsed flow of a tungsten fluoride compound to convert the boron layer to a tungsten layer that is conformal to the feature. This may be performed as discussed above with respect to operation 404 of FIG. 4 and FIG. 6. Operations 702 and 704 may be performed in the same chamber or in different chambers. If in the same chamber, a purge operation may be performed between operations 702 and 704. At 760 in FIG. 711, a tungsten templating layer 753 is depicted after the pulsed CVD process.

Returning to FIG. 7A, in an optional operation 705, the tungsten layer formed in operation 704 is exposed to an inhibition chemistry. The inhibition treatment is a treatment that has the effect of inhibiting subsequent deposition on the treated surfaces. The inhibition may involve various mechanisms depending on the surfaces to be treated, the inhibition chemistry, and whether the inhibition is a thermal or plasma process. In one example, tungsten nucleation, and thus tungsten deposition, is inhibited by exposure to a nitrogen-containing chemistry. This can involve generation of activated nitrogen-containing species by a remote or direct plasma generator, for example, or exposure to ammonia vapor in an example of a thermal (non-plasma) process. Examples of inhibition mechanisms can include a chemical reaction between activated species and the feature surface to form a thin layer of a compound. material such as tungsten nitride (WN) or tungsten carbide (WC). In some embodiments, inhibition can involve a surface effect such as adsorption that passivates the surface without forming a layer of a compound material. The inhibition may be characterized by an inhibition depth and an inhibition gradient. That is, the inhibition may vary with depth, such that the inhibition is greater at the feature opening than at the bottom of the feature and may extend only partway into the feature. In the example of FIG. 7B, at 765, the treated surface is shown at 756 with the inhibition depth being about half of the full feature depth. The inhibition treatment is stronger at the top of the feature, as graphically shown by the dotted line deeper within the feature.

Returning to FIG. 7A, the structure is exposed to a tungsten precursor dose in operation 707. The tungsten precursor can be the same as used in operation 704, or a different precursor. The chamber is purged in an operation 708, followed by exposing the structure to a reducing agent dose in operation 711. The reducing agent can be hydrogen, or another reducing agent. This is followed by purging the chamber in an operation 713. Operations 707-713 define one ALD cycle in some embodiments, with the tungsten precursor adsorbed onto the surface of the feature surface as a result of operation 707 and the reducing agent then reacting with the adsorbed tungsten precursor to form tungsten as a result of operation 711. Other ALD processes may be used; for example, the reducing agent doses may precede the tungsten precursor doses in each cycle. in some embodiments, the reducing agent dose in operation 711 is distinct from that in the operation 702 in that there is no thermal decomposition. Rather, the reducing agent may react or adsorb onto the surface.

Operations 707-713 are repeated then to wholly or partially fill the feature in an operation 714. In FIG. 7B, at 770, the feature is shown during the ALD process (e.g., as represented by operations 707-714) with the feature partially filled with bulk tungsten 754. The large grain templating layer 803 provides a template for continued grain growth of the bulk layer. Because deposition is inhibited near the feature opening, during the ALD process shown at 775, the material preferentially deposits at the feature bottom while not depositing or depositing to a lesser extent at the feature opening. This can prevent the formation of voids and seams within the filled feature. As such, during ALD, the tungsten 754 may be deposited in a manner characterized as bottom-up fill rather than conformal. As the deposition continues, the inhibition effect may be removed, such that deposition on the lightly treated surfaces may no longer be inhibited. This is illustrated at 770, with the treated surfaces 756 being less extensive than prior to the stage. In the example of FIG. 7B, as the ALD proceeds, the inhibition is eventually overcome on all surfaces and the feature is completely filled with the material 754 as shown at 775.

The ALD process may be performed in the same or different chamber as the pulsed CVD process in some embodiments, the substrate may be transferred from a first deposition chamber after the pulsed CVD process to a chamber configured for inhibition treatment, and then transferred to a second deposition chamber for ALD. In some embodiments, the inhibition treatment may be performed in the first or the second deposition chamber.

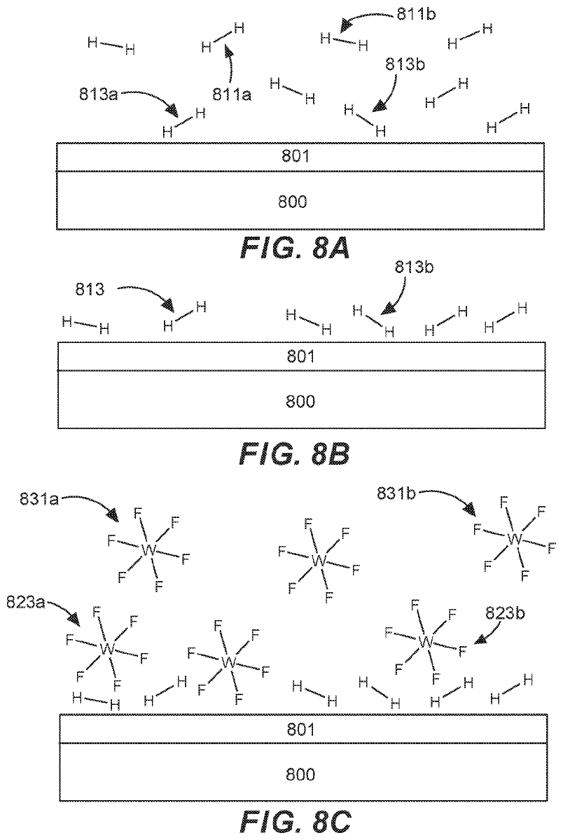

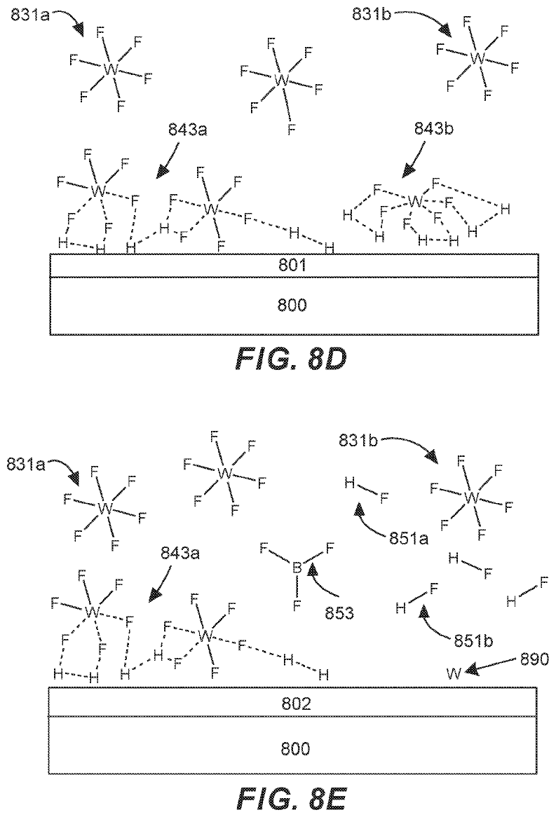

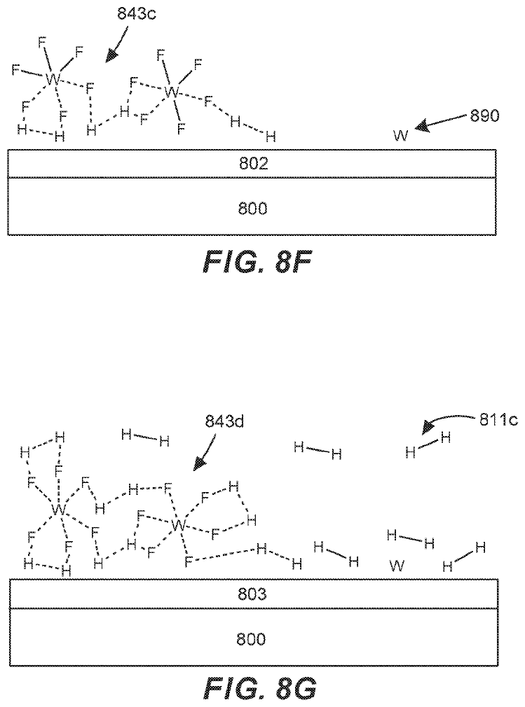

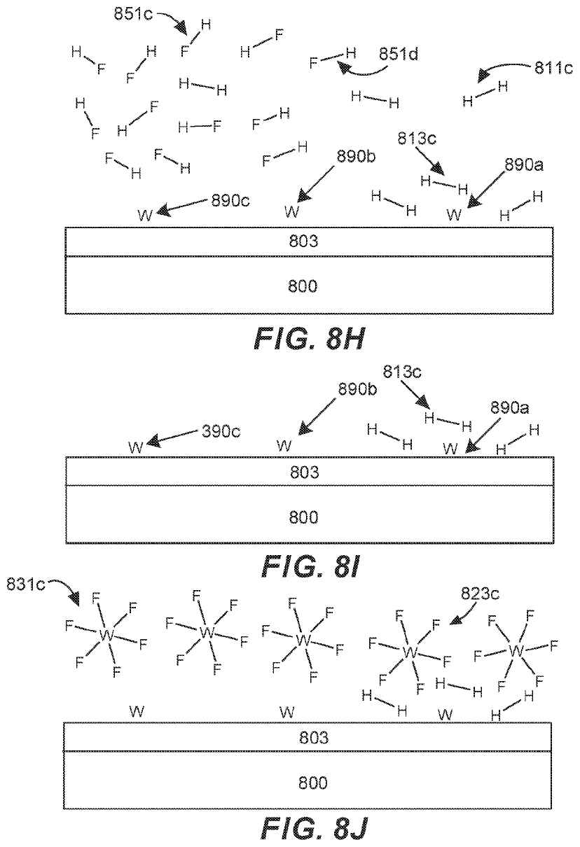

FIGS. 8A-8J are schematic illustrations of an example mechanism of a deposition cycle. FIG. 8A depicts an example mechanism where a substrate including a TiN layer 800 and a B layer 801 is exposed to H₂. Hydrogen is introduced in gas phase (811a and 811b) and some H₂ (813a and 813b) is on the surface of the B layer 801, where it may dissociate into chemically active adsorbed atomic hydrogen or physisorb. For example, H₂ may not necessarily chemisorb onto the B layer 801, but in some embodiments, may physisorb onto the surface of the reducing agent layer 801. This can form a solid B-H interfacial surface layer.

FIG. 8B shows an example illustration whereby H₂ previously in gas phase (811a and 811b in FIG. 8A) are purged from the chamber, and H₂ previously on the surface (843a and 813b) remain on the surface of the reducing agent 801.

FIG. 8C shows an example schematic illustration whereby the substrate is exposed to WF₆, some of which is in gas phase (831a and 831b) and some of which is at or near the surface of the substrate (823a and 823b).

Some H₂ may react with WF₆ that remained on the surface from the prior dose. In FIG. 8D, WF₆ may react with H₂ to temporarily form intermediate 843b, whereby in FIG. 8E, intermediate 843b fully reacts to form tungsten 890 and HF in gas phase (851a. and 851b, for example). WF₆ or an intermediate may also react with B in the reducing agent layer 801 to form BF₃ 853. As such, a layer 802 including B, H, and W is present.

Some H₂ may not fully react with WF₆ (or other W fluorides) that remain on the surface from the prior dose. As shown in FIG. 8D, WF₆ may partially react with H₂ to form intermediate 843a, whereby in FIG. 8E, intermediate 843a remains partially reacted. Film deposited using a fluorine-containing tungsten precursor and hydrogen has a lower resistivity than a film deposited using a borane, silane, or germane. The bulk tungsten films deposited as described herein have low resistivity associated with H₂ reduction.

The stoichiometry of WF₆ may use at least three H₂ molecules to react with one molecule of WF₆. It is possible that WF₆ partially reacts with molecules of H₂ but rather than forming tungsten, an intermediate is formed. For example, this may occur if there is not enough H₂ in its vicinity to react with WF₆ based on stoichiometric principles (e.g., three H₂ molecules are used to react with one molecule of WF₆) thereby leaving an intermediate 843a on the surface of the substrate.

FIG. 8F provides an example schematic of the substrate when the chamber is purged. Note that compound 843c of FIG. 4F may be an intermediate formed but not completely reacted, while some tungsten 890 is present. Each cycle may thereby form a sub-monolayer of tungsten on the substrate.

As an example, FIG. 8G shows an illustration where H₂ 811c in gas phase is introduced to the substrate with the deposited tungsten 890 and the partially reacted intermediate 843d thereon. At this stage, all of the B in the reducing agent layer has been converted, leaving a W film 803. Note that as shown in FIG. 8G, the H₂ introduced may now fully react with the intermediate 843d on the substrate such that, as shown in FIG. 8H, the reacted compound 843d leaves behind deposited tungsten 890b and 890c, and byproducts HF 851c and 851d are formed in gas phase. Some H₂ 811c may remain in gas phase, while some H₂ 813c may remain on the tungsten layer 890a.

In FIG. 8I, the chamber is purged leaving behind deposited tungsten 490a, 490b, and 490c, and some H₂ 413c. In FIG. 8J, WF₆ is again introduced in a dose such that molecules 831c and 823c may then adsorb and/or react with H₂ and the substrate. WF₆ dose, the chamber may again be purged, and cycles may be repeated again until the desired thickness of tungsten is deposited.

While the deposition of tungsten films described herein may include some amount of impurities such as nitrogen, carbon, oxygen, boron, phosphorous, sulfur, silicon, germanium and the like, depending on the particular precursors and processes used. Moreover, while the deposition of elemental tungsten is described, the methods described above may be modified to deposit doped or compound films. For example, a dopant source may be included in the pulsed CVD and/or ALD depositions described above. The tungsten content in the film may range from 20% to 100% (atomic) tungsten. In many implementations, the films are tungsten-rich, having at least 50% (atomic) tungsten, or even at least about 60%, 75%, 90%, or 99% (atomic) tungsten. In some implementations, the films may be a mixture of metallic or elemental tungsten (W) and other tungsten-containing compounds such as tungsten carbide (WC), tungsten nitride (WN), etc.

### Experimental

Five processes were run to deposit tungsten on titanium nitride: 1) non-pulsed CVD; 2 and 3) ALD; and 3 and 4) pulsed CVD. Process conditions and deposition rates are shown below.

| | | WF₆ | | | | |
|---|---|---|---|---|---|---|
| | H₂ | divert/charge/ | H₂ | WF₆ flow | | |
| | dose/purge | dose/purge | flow rate | rate | Dep rate | |
| Process | time (s) | times (s) | (sccm) | (sccm) | (Angstrom/s) | |
| 1 - CVD | n/a (continuous | n/a (continuous | 4750 | 270 | 1.7 | |
| | flow) | flow) | | | | |
| 2 - ALD | 1/4 | 2/1/1/7 | 5000 | 300 | 0.03 | (0.4 Å/cycle) |
| 3 - ALD | 1/2 | 0.5/0.5/1/2 | 5000 | 300 | 0.06 | (0.37 Å/cycle) |
| 4 - pulsed | n/a (continuous | 1/1/1/7 | 5000 | 300 | 0.3 | (3.03 Å/cycle) |
| CVD | flow) | | | | | |
| 5 - pulsed | n/a (continuous | 0.5/0.5/1/2 | 5000 | 100 | 0.51 | (2.02 Å/cycle) |

| | |
|---|---|
| CVD | flow) |

Deposition rates for the pulsed CVD processes are significantly greater than for the ALD processes.

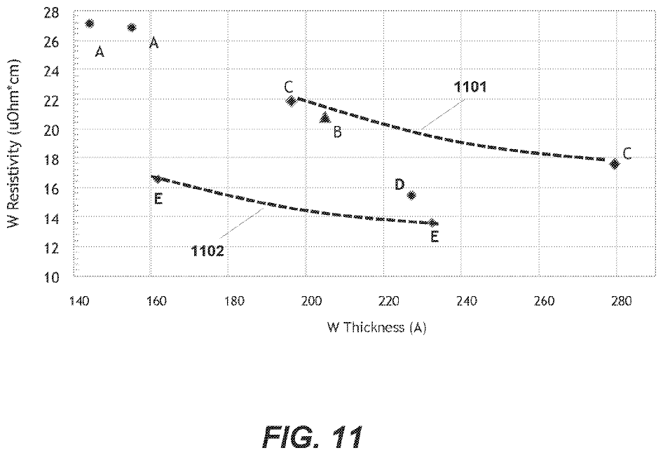

FIG. 11 shows resitivity results for various tungsten deposition processes:
A—Nuc-less ALD; data points from processes 2 and 3 in the above table
B—Nuc-less (non-pulsed) CVD; data point from process 1 in the above table
C—ALD W with nucleation layer
D—Nuc-less pulsed CVD; data point from process 4 in the above table
E—Nuc-less pulsed CVD, data points from process 5 in the above table
Nuc-less refers to tungsten film deposited without a nucleation layer.
Line 1101 reflects process C and line 1102 reflects process E, connecting data points at two different thicknesses as resisitivity decreases with increasing thickness. Comparing lines 1101 and 1102, the nuc-less pulsed CVD shows a 20%-30% resitivity reduction over ALD W deposited on a nucleation layer.

SIMS analysis of films deposited using nucleation-free non-pulsed CVD and nucleation-free pulsed CVD with WF₆ show fluorine (F) content that is an order of magnitude less for the pulsed CVD in the deposited tungsten film. Specifically, the F content in the non-pulsed CVD film was about 10²⁰ atoms/cm³ and about 10¹⁹ atoms/cm³ in the pulsed CVD film. The latter is comparable to ALD deposition with a nucleation layer.

An x-ray diffraction (XRD) analysis of grain size of 200 Angstrom tungsten films deposited by ALD on a nucleation layer and a nucleation-free pulsed CVD process.

| Film | Phase | Crystallite Size | % random |
|---|---|---|---|
| Nucleation + ALD | Cubic | 12.7 ± 3.2 | 4.1 |
| W (200 Angstroms) | | | |
| Nucleation-free + | Cubic | 18.8 ± 0.9 | 42.3 |
| CVD W (200 | | | |
| Angstroms) | | | |

The crystallite size is significantly large for the pulsed CVD process. Large grain size results in lower resistivity. The growth is more random—that is oriented in different direction, indicating that the growth mechanism is fundamentally different.

### Apparatus

Any suitable chamber may be used to implement the disclosed embodiments. Example deposition apparatuses include various systems, e.g., ALTUS® and ALTUS® Max, available from Lam Research Corp., of Fremont, California, or any of a variety of other commercially available processing systems. In some embodiments, deposition of a reducing agent layer may be performed at a first station that is one of two, five, or even more deposition stations positioned within a single deposition chamber. Thus, for example, diborane (B₂H₆) may be introduced to the surface of the semiconductor substrate, at the first station, using an individual gas supply system that creates a localized atmosphere at the substrate surface to form a boron layer. Another station may be used for tungsten conversion of the boron layer. In the same or other embodiments, two or more stations may be used to fill the features with bulk tungsten in parallel processing.

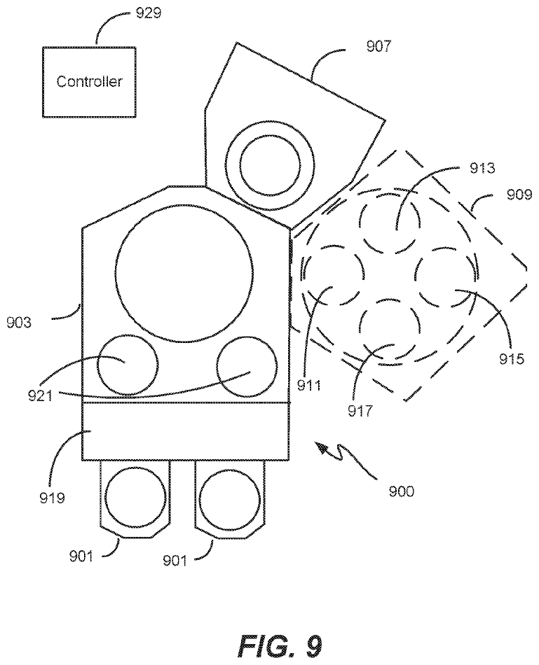

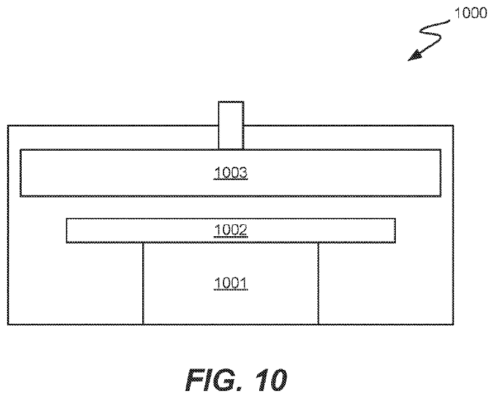

FIG. 9 is a block diagram of a processing system suitable for conducting deposition processes in accordance with embodiments. The system 900 includes a transfer module 903. The transfer module 903 provides a clean, pressurized environment to minimize risk of contamination of substrates being processed as they are moved between various reactor modules. Mounted on the transfer module 903 is a multi-station reactor 909. Multi-station reactor 909 may also be used to perform reducing agent layer deposition, tungsten conversion, and subsequent CVD in some embodiments. Reactor 909 may include multiple stations 911, 913, 915, and 917 that may sequentially perform operations in accordance with disclosed embodiments. For example, reactor 909 could be configured such that station 911 performs a first operation using a reducing agent and stations 913, 915, and 917 perform operations pulsing WF₆ and H₂. Each station may include a heated pedestal or substrate support for independent temperature control, one or more gas inlets or showerhead or dispersion plate. An example of a deposition station 1000 is depicted in FIG. 10, including substrate support 1002 and showerhead 1003. A heater may be provided in pedestal portion 1001.

Also mounted on the transfer module 903 may be one or more single or multi-station modules 907 capable of performing plasma or chemical (non-plasma) pre-cleans. The module may also be used for various treatments to, for example, prepare a substrate for a deposition process. The system 900 also includes one or more wafer source modules 901, where wafers are stored before and after processing. An atmospheric robot (not shown) in the atmospheric transfer chamber 919 may first remove wafers from the source modules 901 to loadlocks 921. A wafer transfer device (generally a robot arm unit) in the transfer module 903 moves the wafers from loadlocks 921 to and among the modules mounted on the transfer module 903.

In some embodiments, different modules are used for different stages of the process. For example, boron deposition and conversion to tungsten may be performed in a first chamber, a second chamber for plasma treatment for inhibition, and a third chamber may be used for ALD W growth for bulk fill.

In various embodiments, a system controller 929 is employed to control process conditions during deposition. The controller 929 will typically include one or more memory devices and one or more processors. A processor may include a CPU or computer, analog and/or digital input/output connections, stepper motor controller boards, etc.

The controller 929 may control all of the activities of the deposition apparatus. The system controller 929 executes system control software, including sets of instructions for controlling the timing, mixture of gases, chamber pressure, chamber temperature, wafer temperature, wafer chuck or pedestal position, and other parameters of a particular process. Other computer programs stored on memory devices associated with the controller 929 may be employed in some embodiments.

Typically, there will be a user interface associated with the controller 929. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general-purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any computer readable programming language: for example, assembly language, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe and may be entered utilizing the user interface.

Signals for monitoring the process may be provided by analog and/or digital input connections of the system controller 929. The signals for controlling the process are output on the analog and digital output connections of the deposition apparatus 900.

The system software may be designed or configured in many different ways. For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code.

In some implementations, a controller 929 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 929, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller 929, in some implementations, may be a part of or coupled to a computer that is integrated with, coupled to the system, otherwise networked to the system, or a combination thereof. For example, the controller 929 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The controller 929 may include various programs. A substrate positioning program may include program code for control ling chamber components that are used to load the substrate onto a pedestal or chuck and to control the spacing between the substrate and other parts of the chamber such as a gas inlet and/or target. A process gas control program may include code for controlling gas composition, flow rates, pulse times, and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck.

Examples of chamber sensors that may be monitored during deposition include mass flow controllers, pressure sensors such as manometers, and thermocouples located in the pedestal or chuck. Appropriately programmed feedback and control algorithms may be used with data from these sensors to maintain desired process conditions.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically includes some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

In the description above and in the claims, numerical ranges are inclusive of the end points of the range. For example, “between about 10 and 50 Angstroms thick” includes 10 Angstroms and 50 Angstroms. Similarly, ranges represented by a dash are inclusive of the end points of the ranges.

In the foregoing description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments. It will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method comprising:
depositing an tungsten bulk layer without depositing a tungsten nucleation layer on a surface of a substrate by:
forming a layer comprising elemental boron (B) on the surface; and
after forming the layer, performing a pulsed chemical vapor deposition (CVD) process to convert the layer comprising elemental boron to a tungsten layer, wherein the pulsed CVD process comprises exposing the substrate to a continuous flow of hydrogen (H₂) and while exposing the substrate to a continuous flow of H₂, exposing the substrate to pulses of a tungsten precursor separated by intervals.

2. The method of claim 1, wherein the B content at the interface of the elemental tungsten bulk layer and the surface is no more than 10²¹ atoms/cm³.

3. The method of claim 1, wherein the layer comprising elemental boron is between 10 and 50 Angstroms thick.

4. The method of claim 1, wherein the layer comprising elemental boron consists essentially of boron.

5. The method of claim 1, wherein the surface is a nitride surface.

6. The method of claim 1, wherein the surface is a titanium nitride surface.

7. The method of claim 1, wherein the surface is an oxide surface.

8. The method of claim 1, wherein forming the layer comprising elemental boron comprises exposing the surface to diborane.

9. The method of claim 1, wherein the operations of forming the layer comprising elemental boron and performing the pulsed CVD process are performed in the same chamber.

10. The method of claim 1, wherein forming a layer comprising elemental boron (B) on the surface comprises thermal decomposition of a boron-containing reducing agent without adsorption of the boron-containing reducing agent on the surface.

11. The method of claim 1, wherein the substrate comprises one or more features to be filled with tungsten.

12. The method of claim 11, wherein the layer of elemental boron conforms to the surface topography.

13. The method of claim 11, further comprising, after converting the layer comprising elemental boron to a tungsten layer, continuing the pulsed CVD process to deposit tungsten in the feature.

14. The method of claim 11, further comprising, after converting the layer comprising elemental boron to a tungsten layer, performing an ALD process to deposit tungsten in the feature.

15. The method of claim 14, wherein the ALD process is performed in a different chamber as the pulsed CVD process.

16. The method of claim 14, wherein the ALD process is performed in the same chamber as the pulsed CVD process.

17. The method of claim 14, further comprising exposing the tungsten layer to an inhibition chemistry prior to the ALD process.

18. The method of claim 17, wherein the inhibition chemistry is nitrogen-containing.

19. The method of claim 1, wherein the duration of the pulses of tungsten precursor is less than the duration of the intervals between pulses.

20. The method of claim 1, wherein the pulsed CVD process is performed at a temperature of no more than 350° C.

21. The method of claim 1, wherein the pulsed CVD process is performed at a temperature of no more than 300° C.

22. The method of claim 1, wherein the layer of tungsten is between 10 and 50 Angstroms thick.
